(19) United States
(12) Patent Application Publication
(10) Pub. No.: US 2012/0313172 A1
(43) Pub. Date: Dec. 13, 2012

(54) SEMICONDUCTOR DEVICE, SEMICONDUCTOR WAFER, AND METHODS OF MANUFACTURING THE SAME

(75) Inventors: Masaharu MATSUDAIRA, Kanagawa (JP); Toshiharu Nagumo, Kanagawa (JP); Hiroshi Takeda, Kanagawa (JP); Kiyoshi Takeuchi, Kanagawa (JP)

(73) Assignee: Renesas Electronics Corporation

(21) Appl. No.: 13/489,128

(22) Filed: Jun. 5, 2012

(30) Foreign Application Priority Data
Jun. 7, 2011 (JP) 2011-127629

(51) Int. Cl. H01L 27/088; H01L 21/762; H01L 21/20; H01L 29/02

(52) U.S. Cl. 257/347; 257/632; 438/400; 438/479; 257/E27.06; 257/E29.002; 257/E21.09; 257/E21.545

(57) ABSTRACT

This invention is to provide a semiconductor device having a reduced variation in the transistor characteristics. The semiconductor device has a SOI substrate, a first element isolation insulating layer, first and second conductivity type transistors, and first and second back gate contacts. The SOI substrate has a semiconductor substrate having first and second conductivity type layers, an insulating layer, and a semiconductor layer. The first element isolation insulating layer is buried in the SOI substrate, has a lower end reaching the first conductivity type layer, and isolates a first element region from a second element region. The first and second conductivity type transistors are located in the first and second element regions, respectively, and have respective channel regions formed in the semiconductor layer. The first and second back gate contacts are coupled to the second conductivity type layers in the first and second element regions, respectively.

### CROSS-REFERENCE TO RELATED APPLICATIONS

The disclosure of Japanese Patent Application No. 2011-127629 filed on Jun. 7, 2011 including the specification, drawings and abstract is incorporated herein by reference in its entirety.

### BACKGROUND

The present invention relates to a semiconductor device, a semiconductor wafer, and methods of manufacturing them.

In recent years, with the miniaturization of MOS devices, variation in the transistor characteristics due to discreteness of an impurity in the channel thereof have become a problem. A MOS device having a SOI (Silicon On Insulator) structure has an advantage of decreasing the impurity concentration in the channel and thereby lessening variation, while suppressing a short channel effect. Furthermore, in a SOI device, the threshold value of a transistor can be controlled not by controlling the threshold value of the transistor by a channel impurity concentration but by applying a voltage below a BOX (Buried Oxide) layer.

Such a technology is described, for example, in Patent Document 1. The semiconductor device described in Patent Document 1 has a p substrate, N wells provided in the P substrate, a BOX layer formed over the N wells, NMOS, and PMOS. The N wells below the BOX layers of the NMOS and the PMOS have the same polarity. The N wells adjacent to each other are isolated from each other by a PN junction with the P substrate and they have a sufficient space therebetween so as to prevent electrical coupling to each other.

The semiconductor device described in Patent Document 2 has a P well provided below the BOX layer of NMOS and an N well provided below the BOX layer of PMOS and has a triple well structure for electrically isolating the N well from the P well. These wells are formed by forming an element isolation film in an SOI substrate to form an N channel region and a P channel region and then implanting impurities into the substrate via a SOI layer which will be each channel region.

Patent Document 3 describes an SOI substrate obtained by stacking a support substrate, a BOX layer, and a SOI layer in order of mention. In this support substrate, a well pattern of an N well and a P well is formed in advance depending on a circuit pattern so that in the technology described in Patent Document 3, a design change in circuit pattern requires another SOI substrate having a pattern corresponding to it. In addition, an element isolation film penetrates through the SOI layer but it extends to only the upper surface of the BOX layer. Well patterns of the same conductivity type must therefore be separated from each other sufficiently to prevent electrical coupling of them. In addition, Non-patent Document 1 describes a SOI substrate obtained by forming, on a support substrate, a first BOX layer, a second BOX layer, and a SOI layer in order of mention. This document describes a structure in which an electrode made of polysilicon is buried between the first and second BOX layers. This buried electrode is electrically isolated from the underlying support substrate via the second BOX layer.
[Patent Document 1] Japanese Patent Laid-Open No. 2005-26353
[Patent Document 2] Japanese Patent Laid-Open No. 2009-135140
[Patent Document 3] Japanese Patent Laid-Open No. 2004-179506
[Non-patent Document 1] M. Khater et al., Symposium on VLSI Technology 2010, p. 43.

### SUMMARY

In the typical semiconductor device, a well inside a SOI substrate and below a BOX layer configuring the SOI substrate is formed by ion implantation. By ion implantation, an impurity therefore reaches inside the substrate through a SOI layer which will be a channel region of a transistor. As a result of investigation by the present inventors, however, a portion of the implanted impurities remain in the SOI layer and it may cause variation in the transistor characteristics.

The present inventors thought that formation of an impurity layer, which will be a back gate in the semiconductor substrate, prior to the formation of the SOI layer on the semiconductor substrate eliminates necessity of implanting ions into the SOI layer which will be a channel region, making it possible to suppress variation in the transistor characteristics. As a result of the investigation, they have found that a semiconductor device having the following configuration is suited.

The present invention provides a semiconductor device including a SOI substrate having a semiconductor substrate having a first conductivity type layer and a second conductivity type layer formed thereon, an insulating layer formed on the semiconductor substrate, and a semiconductor layer formed on the insulating layer, a first element isolation insulating layer buried in the SOI substrate, having a lower end reaching the first conductivity type layer, and isolating a first element region from a second element region, a first conductivity type transistor located in the first element region and having a channel region formed in the semiconductor layer, a second conductivity type transistor located in the second element region and having a channel region formed in the semiconductor layer, a first back gate contact coupled to the second conductivity type layer located in the first element region, and a second back gate contact coupled to the second conductivity type layer located in the second element region. The second conductivity type impurity concentration of the second conductivity type layer is 10¹⁸ atoms/cm³ or greater. The second conductivity type impurity concentration of the semiconductor layer on which the first conductivity type transistor is formed is not greater than 1/10 of the second conductivity type impurity concentration of the second conductivity type layer.

The invention also provides a semiconductor device including a semiconductor substrate having a first conductivity type layer and a second conductivity type layer formed thereon; a second element separation layer buried in the semiconductor substrate, having a lower end reaching the first conductivity type layer, and isolating, from a bulk region, a SOI region further having an insulating layer formed on the semiconductor substrate and a semiconductor layer formed on the insulating layer; a first element isolation insulating layer buried in the semiconductor substrate located in the SOI region, having a lower end reaching the first conductivity type layer, and isolating a first element region from a second element region; a first conductivity type first transistor located in the first element region and having a channel region formed in the semiconductor layer; a second conductivity type first transistor located in the second element region and having a channel region formed in the semiconductor layer; a first conductivity type second transistor located in the bulk region and formed on the second conductivity type layer; a first back gate contact coupled to the second conductivity type layer located in the first element region; and a second back gate contact coupled to the second conductivity type layer located in the second element region. The second conductivity type impurity concentration of the second conductivity type layer is 10¹⁸ atoms/cm³ or greater. The second conductivity type impurity concentration of the semiconductor layer on which the first conductivity type transistor is formed is not greater than 1/10 of the second conductivity type impurity concentration of the second conductivity type layer.

The invention further provides a semiconductor wafer equipped with a SOI substrate having a semiconductor substrate having a first conductivity type layer and a second conductivity layer formed thereon, an insulating layer formed on the semiconductor substrate, and a semiconductor layer formed on the insulating layer. In a planar view, supposing that the area of the first conductivity type layer is S1 and the area of the second conductivity type layer is S2, a proportion of S2/S1 is 80% or greater.

Further, the invention provides a method of manufacturing a semiconductor device, which includes the steps of: preparing a SOI substrate having a semiconductor substrate having a first conductivity type layer and a second conductivity type layer formed thereon, an insulating layer formed on the semiconductor substrate, and a semiconductor layer formed on the insulating layer; forming a first element isolation insulating layer buried in the SOI substrate, having a lower end reaching the first conductivity type layer, and isolating a first element region from a second element region; forming a first conductivity type first transistor located in the first element region and having a channel region formed in the semiconductor layer; forming a second conductivity type first transistor located in the second element region and having a channel region formed in the semiconductor layer; coupling a first back gate contact to the second conductivity type layer located in the first element region; and coupling a second back gate contact to the second conductivity type layer located in the second element region.

The invention also provides a method of manufacturing a semiconductor wafer including the steps of: forming a second conductivity type layer on a first conductivity type layer to obtain a first semiconductor substrate, forming an insulating layer on a semiconductor layer to obtain a second semiconductor substrate; and facing the second conductivity type layer and the insulating layer to each other to bond the first semiconductor substrate and the second semiconductor substrate to each other.

Incidentally, in the method of manufacturing a semiconductor wafer and the method of manufacturing a semiconductor device according to the invention, a plurality of steps is described in order. The order of steps does not always limit the order of carrying out a plurality of steps unless otherwise specifically indicated. When the method of manufacturing a semiconductor wafer or semiconductor device is conducted, the order of the steps can be changed insofar as it does not adversely affect the invention. It is not necessary to carry out the manufacturing method of a semiconductor wafer or semiconductor device in the invention while differentiating timing of the steps. During a certain step is performed, another step may occur. Timing of a certain step may partially or wholly overlap with the timing of another step.

The invention provides a semiconductor device having reduced variation in the transistor characteristics.

### BRIEF DESCRIPTION OF DRAWINGS

FIG. 1 is a cross-sectional view showing the configuration of a semiconductor device according to a first embodiment;

FIG. 2 is a cross-sectional view showing the configuration of a semiconductor wafer according to present embodiment;

FIGS. 3(a), 3(b), 3(c), and 3(c) are cross-sectional views of steps showing manufacturing procedures of the semiconductor wafer according to present embodiment;

FIG. 4 is a plan view showing the configuration of the semiconductor device according to the first embodiment;

FIGS. 5(a) and 5(b) are cross-sectional views of steps showing the manufacturing procedures of the semiconductor device according to the first embodiment;

FIGS. 6(a) and 6(b) are cross-sectional views of steps showing the manufacturing procedures of the semiconductor device according to the first embodiment;

FIGS. 7(a) and 7(b) are cross-sectional views of steps showing the manufacturing procedures of the semiconductor device according to the first embodiment;

FIG. 8 is a step cross-sectional view showing the manufacturing procedure of the semiconductor device according to the first embodiment;

FIG. 9 is a cross-sectional view showing the configuration of a semiconductor device according to a second embodiment;

FIG. 10 is a plan view showing the configuration of the semiconductor device according to the second embodiment;

FIG. 11 is a plan view showing a planar layout of the semiconductor device according to the second embodiment;

FIGS. 12(a) and 12(b) are cross-sectional views of steps showing the manufacturing procedures of the semiconductor device according to the second embodiment;

FIGS. 13(a) and 13(b) are cross-sectional views of steps showing the manufacturing procedures of the semiconductor device according to the second embodiment;

FIGS. 14(a) and 14(b) are cross-sectional views of the steps showing the manufacturing procedures of the semiconductor device according to the second embodiment;

FIG. 15 is a cross-sectional view of a step showing the manufacturing procedure of the semiconductor device according to the second embodiment;

FIGS. 16(a), 16(b), and 16(c) are graphs showing impurity concentrations below the BOX layer according to the present embodiment; and

FIG. 17 is a plan view showing a modification example of the configuration of the semiconductor device according to the second embodiment.

### DETAILED DESCRIPTION

The embodiments of the invention will hereinafter be described referring to drawings. In all the drawings, like constituent elements are identified by like reference numerals and a description will be omitted as needed.

### First Embodiment

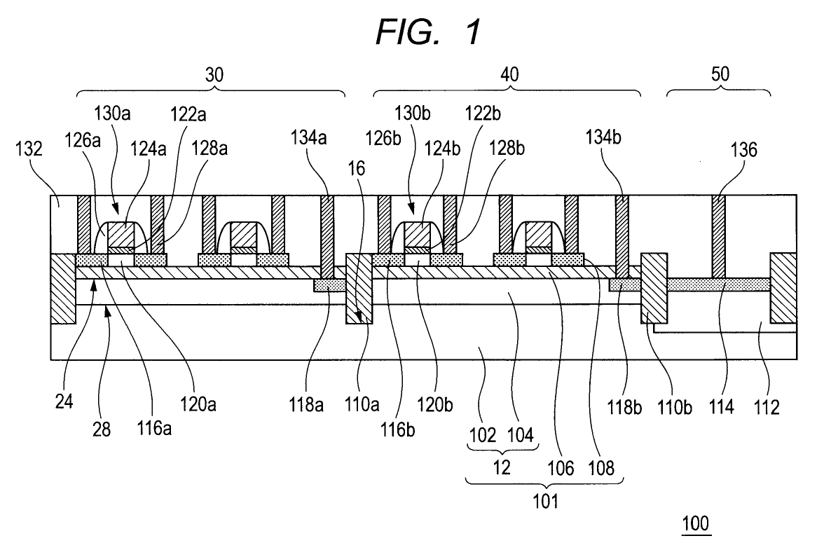

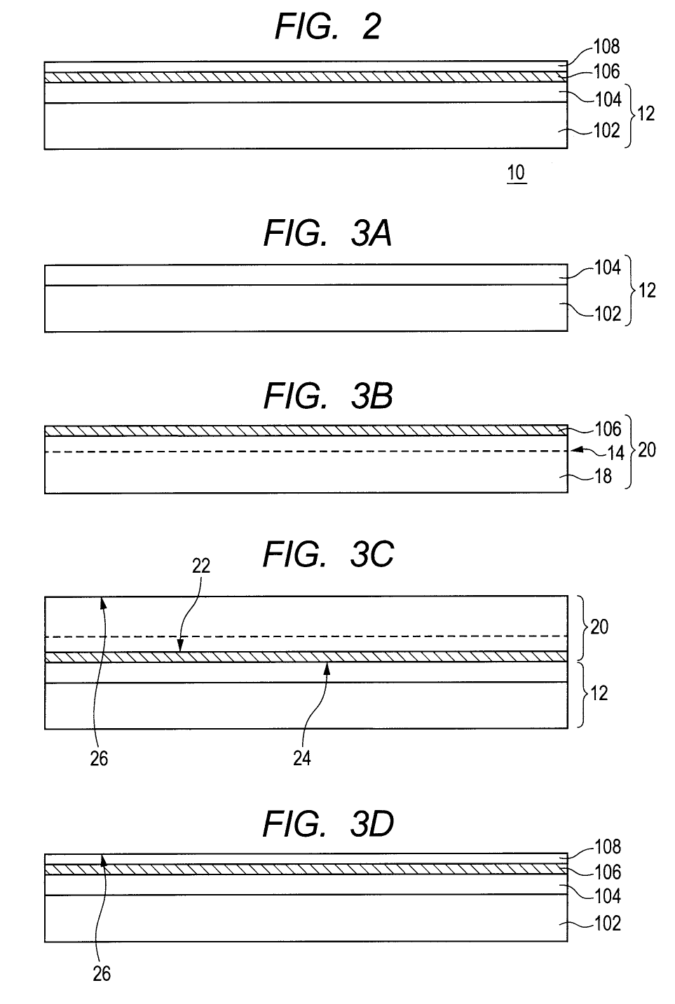

FIG. 1 is a cross-sectional view showing the configuration of a semiconductor device according to a first embodiment. FIG. 2 is a cross-sectional view showing the structure of a semiconductor wafer according to the present embodiment. A semiconductor device 100 of the present embodiment is equipped with a SOI substrate, a first element isolation insulating layer, a first conductivity type transistor, a second conductivity type transistor, a first back gate contact, and a second back gate contact.

A SOI substrate 101 has a semiconductor substrate 12 having a second conductivity type layer (N type semiconductor layer 104) formed on a first conductivity type layer (P type semiconductor layer 102), an insulating layer 106 (BOX layer) formed on the semiconductor substrate 12, and a semiconductor layer (SOI layer 108) formed on the insulating layer 106. A first element isolation insulating layer (element isolation layer 110a) is buried in the SOI substrate 101, having a lower end 16 reaching the first conductivity type layer (P type semiconductor layer 102) and isolating a first element region (PFET region 40) from a second element region (NFET region 30). A first conductivity type transistor (P type transistor 130b) is located in the first element region (PFET region 40) and has a channel region 120b formed in the semiconductor layer (SOI layer 108). A second conductivity type transistor (N type transistor 130a) is located in the second element region (NFET region 30) and has a channel region 120a formed in the semiconductor layer (SOI layer 108). A first back gate contact (back gate contact 134b) is coupled to the second conductivity type layer (N type semiconductor layer 104) located in the first element region (PFET region 40). A second back gate contact (back gate contact 134a) is coupled to the second conductivity type layer (N type semiconductor layer 104) located in the second element region (NFET region 30).

In the present embodiment, a description is made supposing that the first conductivity type is P type and the second conductivity type is N type. A similar effect can be attained even if the first conductivity type is N type and the second conductivity type is P type. First, the present embodiment is outlined.

In the semiconductor device 100 of the present embodiment, the NFET region 30 and the PFET region 40 (which may be called “PN region”, collectively) are two regions electrically isolated by a PN junction between the P type semiconductor layer 102 and the N type semiconductor layer 104 and the element isolation layer 110a. The back gate contact 134a is formed in the NFET region 30, while the back gate contact 134b is formed in the PFET region 40. Application of respective potentials to these back gate contacts enables independent control of substrate potentials in regions having different conductivity types, respectively. The potentials of these back gate contacts may be the same or different.

In addition, according to the present embodiment, a structure having a P region and an N region as isolated regions can be formed easily by using the semiconductor wafer 10 shown in FIG. 2. This point will be described next. The semiconductor wafer 10 of the present embodiment has a first conductivity type layer (P type semiconductor layer 102), a second conductivity type layer (N type semiconductor layer 104), an insulating layer 106, and a semiconductor layer (SOI layer 108). The N type semiconductor layer 104 forms a PN junction with the P type semiconductor layer 102. When element isolation layers are formed at a position which will be a boundary of a PN region in the N type semiconductor layer 104, the N type semiconductor layer 104 can be divided into two or more easily.

On the other hand, the N type semiconductor layer 104 of the semiconductor wafer 10 functions as a back gate so that when the N type semiconductor layer 104 is divided, a back gate is formed in each the P and N regions. A back gate contact is formed in each of the N type semiconductor layers 104 thus divided. This makes it possible to apply an independent potential to the back gate contact and thereby controlling the substrate potential of each region freely.

It is the common practice to form a well in a semiconductor substrate in a SOI substrate in order to electrically isolate P and N regions from each other. Such a structure can be obtained in the following procedure when a related-art method is employed. First, an insulating layer and a SOI layer are stacked in order of mention on the semiconductor substrate. Then, ion implantation is performed to form a well in the semiconductor substrate via the SOI layer. Usually, an impurity is implanted deeply in the semiconductor substrate so that the impurity sometimes diffuses in the horizontal direction of the substrate, exceeding the depth of the element isolation layer. This makes it difficult to attain miniaturization. In addition, an impurity implanted deeply may damage the surface and decrease a yield. One measure to overcome such problems is shallow implantation of an impurity into the semiconductor substrate, but shallow implantation facilitates remaining of the impurity in the SOI layer. In this case, for example, a well having a concentration of 10¹⁸ atoms/cm³ or greater is formed in the semiconductor substrate below the insulating layer. Such a concentration is ordinarily necessary for effective functioning of the back gate. In this case, an ion implantation method is employed so that an impurity at least the same level as about 10¹⁸ atoms/cm³ remains in the SOI layer on the insulating layer. In the typical well formation method, however, remaining of an impurity at such a concentration during the ion implantation may cause a variation in the transistor characteristics.

In the present embodiment, on the other hand, a substrate having an impurity layer (second conductivity type layer) formed in the semiconductor substrate prior to the formation of a SOI layer is used as the SOI substrate. Such a SOI substrate (for example, the semiconductor wafer 10) can be obtained by the steps of the semiconductor wafer 10 which will be described later. When such a SOI substrate is used, it is not necessary to implant an impurity into the semiconductor substrate via the SOI layer. According to the present embodiment, therefore, a variation in the transistor characteristics, which will otherwise occur due to the impurity remained in the SOI layer, as described above can be prevented.

In the semiconductor device 100 of the present embodiment, the second conductivity type impurity concentration of the second conductivity type layer (N type semiconductor layer 104) is specified to 10¹⁸ atoms/cm³ or greater and the second conductivity type impurity concentration of the semiconductor layer (SOI layer 108) on which the first conductivity type transistor (P type transistor 130b) has been formed is specified to 1/10 or less of the second conductivity type impurity concentration of the second conductivity type layer (N type semiconductor layer 104) (it is preferred in the present embodiment that the impurity concentration is specified to 1/10 or less of the second conductivity type impurity concentration of the second conductivity type layer (N type semiconductor layer 104) located in the PFET region 40).

In the present embodiment, the fact that the impurity concentration of the second conductivity type (N type which is the same conductivity type as that of the impurity configuring the N type semiconductor layer 104) of the SOI layer 108 is 1/10 or less of the second conductivity type impurity concentration of the second conductivity type layer (N type semiconductor layer 104) means that an SOI substrate obtained by forming an impurity layer (second conductivity type layer) in the semiconductor substrate prior to the formation of the SOI layer is used. In other words, this means that an impurity is not introduced into the SOI layer 108 simultaneously with the formation of a well in the semiconductor substrate. It is preferred that this second conductivity type impurity concentration is specified by measuring the second conductivity type impurity concentration of the SOI layer 108 formed in the PFET region 40. The PFET region 40 has a conductivity type different from that of the second conductivity type layer so that it becomes possible to obtain a significant second conductivity type impurity concentration compared with the measurement of the second conductivity type impurity concentration of the NFET region having the same conductivity type.

A variation in the second conductivity type impurity concentration of the SOI layer 108 can be suppressed when it is lower. For example, the concentration can be suppressed to preferably 10¹⁷ atoms/cm³ or less, more preferably 10¹⁶ atoms/cm³ or less, still more preferably 10¹⁵ atoms/cm³ or less. This means that in the PFET region 40, the P type impurity concentration of the SOI layer 108 may be in the range (from about 10¹⁷ atoms/cm³ to 10¹⁵ atoms/cm³) which does not almost contribute to a variation or may be the concentration (10¹⁵ atoms/cm³ or less) at which the reverse type, that is, N type impurity scarcely exists. The impurity concentration of the second conductivity type may be either an average value or maximum value, but is specified preferably by the maximum value (in other words, peak concentration). Although no particular limitation is imposed on the impurity concentration of the second conductivity type, it may be measured by measuring it in the thickness direction at the center portion of the SOI layer 108 (channel region 120b) (the term “at the center portion” as used herein means a portion located at an equal distance from both ends of the SOI layer 108, however, the equal distance permits the error of the measurement method). In the present embodiment, for example, SIMS (Secondary Ion Mass Spectrometry) is usable as a method of measuring the impurity concentration.

The SOI layer 108 as described above is formed using the semiconductor wafer 10 of the present embodiment. Next, a manufacturing method of the semiconductor wafer 10 of the present embodiment will be described. FIG. 3 is a cross-sectional view of steps showing the manufacturing procedures of the semiconductor wafer shown in FIG. 2.

The manufacturing method of the semiconductor wafer 10 of the present embodiment has the following steps. First, a first semiconductor substrate (semiconductor substrate 12) is prepared by forming a second conductivity type layer (N type semiconductor layer 104) on a first conductivity type layer (P type semiconductor layer 102). Then, a second semiconductor substrate (semiconductor substrate 20) is prepared by forming an insulating layer 106 on a semiconductor layer 18. The second conductivity type layer (N type semiconductor layer 104) and the insulating layer 106 are then faced to each other and the semiconductor substrate 12 and the semiconductor substrate 20 are bonded. These steps will next be described more specifically.

First, as shown in FIG. 3(a), a P type semiconductor layer 102 is prepared. The P type semiconductor layer 102 can be obtained, for example, by introducing a P type impurity into a silicon substrate. Then, an N type semiconductor layer 104 is formed on the upper surface of the P type semiconductor layer 102. The N type semiconductor layer 104 is formed, for example, by epitaxial growth or ion implantation. In this manner, a semiconductor substrate 12 can be obtained.

Next, as shown in FIG. 3(b), an insulating layer 106 (BOX layer) is formed on the surface of a semiconductor layer 18 (for example, a silicon substrate). The insulating layer 106 is formed, for example, by a thermal oxidation method. In this manner, a semiconductor substrate 20 is obtained. Then, at an arbitrary position of the semiconductor layer 18, a plane (defect-containing plane 14) in which a defect has been formed, for example, by hydrogen ion implantation is formed.

Next, as shown in FIG. 3(c), after the semiconductor substrate 20 is turned over, the semiconductor substrate 20 and the semiconductor substrate 12 are bonded to bring the insulating layer 106 into contact with the N type semiconductor layer 104. Then, at the defect-containing plane 14, a portion of the semiconductor layer 18 is separated. The surface of the semiconductor layer 18 which has remained on the semiconductor substrate 12 is polished. Etching or CMP can be employed for polishing. By this polishing, the thickness of the semiconductor layer 18 is controlled and a SOI layer 108 is formed. Then, as shown in FIG. 3(d), reflow treatment is performed to planarize the surface of the SOI layer 108. By the steps described above, the semiconductor wafer 10 shown in FIG. 1 can be obtained.

In the manufacturing method of the semiconductor wafer 10 according to the present embodiment, the N type semiconductor layer 104 and the SOI layer 108 are formed on semiconductor substrates made as different members, respectively. This means that the N type semiconductor layer 104 can be formed on the P type semiconductor layer 102 having an exposed surface. An impurity implanted during the formation step of the N type semiconductor layer 104 is, therefore, not introduced into the SOI layer 108. This makes it possible to control the impurity concentration, peak concentration depth, junction depth, implantation energy, and the like of the N type semiconductor layer 104 without depending on the SOI layer 108.

The semiconductor wafer 10 of FIG. 2 manufactured by such manufacturing steps is equipped with the SOI substrate having the semiconductor substrate 12 having the first conductivity type layer (P type semiconductor layer 102) and the second conductivity type layer (N type semiconductor layer 104) formed thereon, the insulating layer 106 formed on the semiconductor substrate 12, and the semiconductor layer (SOI layer 108) formed on the insulating layer 106. This semiconductor wafer 10 is specified by that supposing, in a planar view, the area of the first conductivity type layer (P type semiconductor layer 102) is S1 and the area of the second conductivity type layer (N type semiconductor layer 104) is S2, a proportion of S2/S1 is 80% or greater.

In the present embodiment, the proportion of S2/S1 is preferably 80% or greater, more preferably 90% or greater, still more preferably 95% or greater. Although no particular limitation is imposed on the upper limit and it may be, for example, 100% or a margin having no N type impurity introduced therein may be formed at the periphery of the N type semiconductor layer 104 or an N type impurity may not be introduced along a scribe line. In addition, in the present embodiment, in a planar view, the N type semiconductor layer 104 may be partially separated from each other, but it is preferably formed with partial continuity, more preferably formed continuously as a whole. Since the N type semiconductor layer 104 is formed continuously, the N type semiconductor layer 104 can be divided easily in the step conducted later. In other words, back gates having a plurality of layouts can be made from the semiconductor wafer 10 having the same structure, depending on a circuit pattern.

In the present embodiment, the fact that the proportion of S2/S1 is 80% or greater means that a mode in which all the wells formed in the semiconductor substrate are isolated from each other to prevent electrical coupling is excluded.

In the semiconductor wafer 10 of the present embodiment, a PN junction is formed widely or wholly below the BOX layer (insulating layer 106). In addition, the N type semiconductor layer 104 is made thin sufficiently. This makes it possible to function the N type semiconductor layer 104 isolated with a trench as a back gate of a SOI device by using a simple process of forming a trench for isolating the N type semiconductor layer 104 into arbitrary regions. The N type semiconductor layer 104 thus isolated is electrically isolated by the P type semiconductor layer 102. A voltage can therefore be applied independently to the N type semiconductor layers 104 thus isolated. In addition, a manufacturing cost of the semiconductor wafer 10 or the SOI substrate available from the semiconductor wafer 10 can be made as low as that of related-art smart cut SOI substrates.

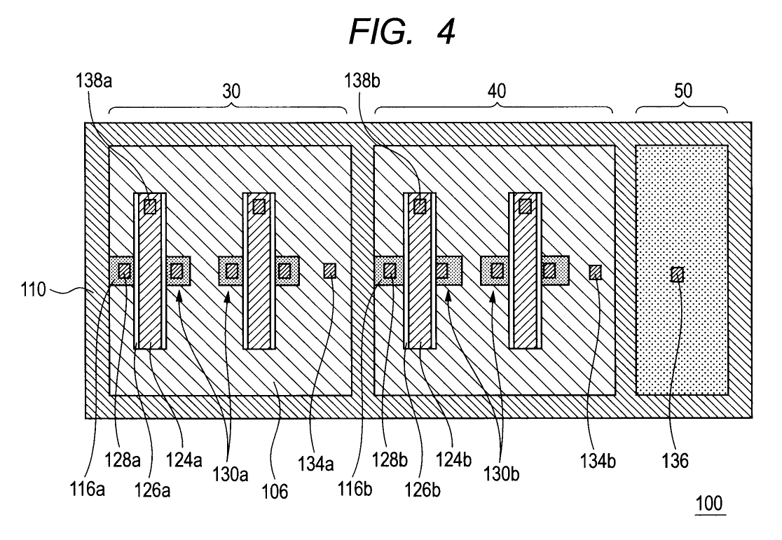

Then, referring to FIG. 1 again, each configuration of the semiconductor device 100 of the present embodiment will next be described specifically. FIG. 4 is a plan view of the semiconductor device 100 shown in FIG. 1. As shown in FIG. 1, the semiconductor device 100 has an NFET region 30, a PFET region 40, and a substrate contact region 50. The NFET region 30 and the PFET region 40 are divided by an element isolation layer 110a, while the PEFT region 40 and the substrate contact region 50 are divided by an element isolation layer 110b. In the NFET region 30, an N type transistor 130a and a back gate contact 134a are formed. In the PFET region 40, a P type transistor 130b and a back gate contact 134b are formed. In the substrate contact region 50, a contact 136 is formed. The N type transistor 130a and the P type transistor 130b are formed on the same semiconductor substrate 12 and they configure a CMOS circuit. Lower ends 16 of the element isolation layers 110a and 110b which divide the regions may reach the junction surface between the P type semiconductor layer 102 and the N type semiconductor layer 104. They are located preferably in the P type semiconductor layer 102.

The N type transistor 130a is formed on the semiconductor substrate 12 in the NFET region 30. One or more N type transistors 130a may be formed in the same NFET region 30. Two or more N type transistors 130a are electrically isolated from each other because the SOI layers 108 are separated from each other. In the present embodiment, the N type transistor 130a is equipped with an N type diffusion region 116a, a channel region 120a, a gate insulating layer 122a, a gate electrode 124a, and a spacer 126a.

The N type diffusion region 116a is formed in the SOI layer 108 and it is formed at both ends of the channel region 120a. The channel region 120a has thereover a contact 128a. The contact 128a penetrates through an interlayer insulating layer 132 and is coupled to, for example, a potential application unit via an upper multilayer wiring. Over a region of the SOI layer 108 in which the gate insulating layer 122a is formed, the gate insulating layer 122a and the gate electrode 124a are formed in order of mention. The SOI layer 108 is formed in a direction perpendicular to the extending direction of the gate electrode 124a. The SOI layer 108 may overlap, in a top view, partially with the gate electrode 124a or it may be formed on the whole surface below the gate electrode 124a. The gate electrode 124a has thereover a contact 138a. The gate electrode 124a has on both sides thereof a spacer 126a. The spacer 126a extends along the extending direction of the gate electrode 124a.

The back gate contact 134a is formed on the semiconductor substrate 12 in the NFET region 30 and is separated from the N type transistor 130a. The back gate contact 134a penetrates through the insulating layer 106 and is coupled to the N type semiconductor layer 104. In the present embodiment, the back gate contact 134a is electrically coupled to the N type semiconductor layer 104 through the N type diffusion layer 118a. The N type diffusion layer 118a is formed in the N type semiconductor layer 104 and is an impurity layer having the same conductivity type as that of the second conductivity type layer. It has preferably a concentration higher than that of the second conductivity type layer. This reduces coupling resistance between the back gate contact 134a and the N type semiconductor layer 104. In the present embodiment, the SOI layer 108 is removed from the periphery of the back gate contact 134a, which is not essential. The SOI layer 108 may be formed insofar as it is separated from the SOI layer 108 configuring the N type transistor 130a (in other words, the back gate contact 134a may be coupled to the N type semiconductor layer 104, penetrating through the SOI layer 108 and the insulating layer 106). The contact in the present embodiment is comprised of an alloy containing W or Cu, an alloy having them as a main component, or a metal composed of such a metal. The contact is formed by Chemical Vapor Deposition (CVD) or damascene process.

On the other hand, the P type transistor 130b is equipped with a P type diffusion region 116b, a channel region 120b, a gate insulating layer 122b, a gate electrode 124b, and a spacer 126b. The P type transistor 130b may have a configuration similar to that of the N type transistor 130a. The back gate contact 134b may have a structure similar to that of the back gate contact 134a.

In the present embodiment, for example, the P type semiconductor layer 102 is a P type silicon substrate; the insulating layer 106 (BOX layer) is a buried insulating layer composed of SiO₂; and the SOI layer 108 is composed of a silicon single crystal. The gate insulating layers 122a and 122b may be a silicon oxynitride film or a high-k film such as hafnium silicate-containing film. The gate electrodes 124a and 124b may be a polycrystalline silicon electrode or a metal gate electrode. It may have, for example, a multilayer structure of polysilicon and TiN.

The substrate contact (contact 136) is coupled to a second well (P well 112) of a first conductivity type located in the substrate contact region 50. The second well (P well 112) of the first conductivity type is formed in the upper layer of the semiconductor substrate 12 (the P type semiconductor layer 102 and the N type semiconductor layer 104) located in the substrate contact region 50. The substrate contact region 50 is isolated from element regions including the first element region (PFET region 40) and the second element region (NFET region 30) by the third element isolation insulating layer (element isolation layer 110b). The element isolation layer 110b is buried in the SOI substrate 101 or in the semiconductor substrate 12 located in the SOI region (the NFET region 30 and the PFET region 40) and it has a lower end reaching the first conductivity type layer (P type semiconductor layer 102).

The contact 136 is coupled to the P well 112 via the P type diffusion layer 114. The P type diffusion layer 114 may have a P type impurity concentration higher than that of the N type semiconductor layer 104. In addition, the P type impurity concentration of the P type diffusion layer 114 may be higher than the P type impurity concentration of the underlying P well 112. For example, when the P type diffusion layer 114 is formed by ion implantation and at the same time, the P well 112 is formed by epitaxial growth, the P type diffusion layer 114 shows a bell-shaped impurity concentration profile, while the P well 112 shows a uniform impurity concentration profile. This means that in a region where the P type diffusion layer 114 is formed, an overlapping region of the bell-shaped profile and the uniform profile of the same conductivity type impurity exists.

In the substrate contact region 50, the insulating layer 106 may be removed completely, but the insulating layer may remain either partially or wholly. In other words, it is not necessary that the insulating layer 106 may not be formed on the whole surface of the semiconductor substrate 12 located in the substrate contact region 50. Alternatively, the insulating layer 106 may be formed on the whole or part of the semiconductor substrate 12 located in the substrate contact region 50. For example, the contact 136 may be coupled to the P well 112, penetrating through the insulating layer 106.

In the present embodiment, it is preferred that a reverse bias is always applied between the N type semiconductor layer 104 and the P type semiconductor layer 102 and they are electrically insulated from each other. Accordingly, a negative potential is preferably applied to the P type semiconductor layer 102. This makes it possible to apply a negative voltage also to the N type semiconductor layer 104 which will be a back gate (which may hereinafter be abbreviated as “BG”) while maintaining the reverse bias of the PN junction. Moreover, the degree of freedom of the applied voltage can be increased. The potential may be given to the P type semiconductor layer 102 from the back side of the substrate, but, as shown in FIG. 1, it can also be applied downward by providing the substrate contact (contact 136). The SOI substrate 101 of the present embodiment can be utilized, for example, in LSI of 22 nm or less. In this case, the power supply voltage in the semiconductor device 100 is about 1V and Vth can be modulated preferably by 0.1V or greater. In order to achieve this at a substrate bias of about 1V equal to the supply source voltage, when the thickness of the gate insulating film (gate insulating layer 122a or 122b) is not greater than 2 nm (in terms of SiO₂, which will equally apply hereinafter), the thickness of the BOX layer (insulating layer 106) is preferably 20 nm or less. When the thickness of the gate insulating film is decreased to about 1 nm, the thickness of the BOX layer is preferably 10 nm or less. The thickness of the insulating layer 106 (BOX layer) is, for example, preferably not greater than 10 times the minimum line width of the gate electrode 130b of the first conductivity type transistor (P type transistor 130b) located in the first element region (PFET region 40), more preferably not greater than one time. When a bulk region, which is a region not having the insulating layer 106, is formed in a region other than the element regions on the semiconductor substrate 12, decreasing the thickness of the insulating layer 106 reduces a difference in height between the element regions and the bulk region, making it possible to provide a semiconductor device excellent in yield.

The N type semiconductor layer 104 is isolated by the element isolation layers 110a. A distance between wells (N type semiconductor layer 104) located in different element regions is preferably 50 nm or less, more preferably 30 nm or less in order to secure a sufficient integration level. On the other hand, the aspect ratio of the element isolation layer 110a is preferably 10 or less, more preferably 5 or less to facilitate manufacturing. Therefore, the thickness of the N type semiconductor layer 104 below the BOX layer (insulating layer 106) is preferably 500 nm or less, more preferably 300 nm or less, still more preferably 150 nm or less.

The impurity concentration of the N type semiconductor layer 104 is adjusted so as to prevent a depletion layer from extending while exceeding the thickness of the layer. Supposing that the depth of the depletion layer is W, the concentration of the N type Si layer is N, and a voltage applied to the depletion layer is V (including an integrated potential), they satisfy the relationship represented by the following equation (a numeral example at V=1V is shown). The unit in the following equation is an SI unit system.

$$W = \sqrt{\frac{2 {ɛ}_{S} V}{qN}} ≅ \sqrt{\frac{1.3 \times {10}^{9} ( {m}^{- 1} )}{N}} \qquad [ Equation 1 ]$$

The impurity concentration of the N type semiconductor layer 104 should be increased sufficiently so as to prevent W calculated by the above equation from exceeding the thickness of the layer. From the standpoint of a Vth modulation efficiency, the width of the depletion layer (in terms of SiO₂) is preferably smaller than the thickness of the BOX layer. This means that when the BOX layer has a thickness of 10 nm, W is preferably not greater than the actual thickness, 30 nm (equivalent to 10 nm since Si has a permittivity three times that of SiO₂). In this case, the concentration N may be adjusted to 10¹⁸ atoms/cm³ or greater.

In the present embodiment, the electrical film thickness of the BOX layer is defined as follows. It is described based on the comparison with the definition of the electrical film thickness of gate insulation. First, a description is made on the electrical film thickness of gate insulation, with electrical film thickness T_{INV} in terms of SiO₂. Supposing that the electrical capacity per area upon inversion is C_{INV} and a permittivity in vacuum is e₀, C_{INV}=3.9 e₀/T_{INV} in which 3.9 is the dielectric constant of SiO₂. When a portion of the gate in contact with the gate insulating film is made of a metal, the gate insulating film is comprised of one or more layers, and the thickness and dielectric constant of layers are T₁ and k₁, T₂ and k₂, . . . , respectively, T_{INV} is roughly T₁×3.9/k₁+T₂x×3.9/k₂+ . . . +0.4 nm, in which 0.4 nm is added because the inversion layer has a limited thickness. When a portion of the gate in contact with the gate insulating film is a semiconductor (typically, polysilicon), T_{INV} is increased further roughly by about 0.4 nm due to a potential drop in the gate (so-called depletion). The following is an example of it. If the gate insulating film of a metal gate MOSFET is a single layer film made of pure SiO₂ having a thickness of 2 nm, its electrical film thickness is 2.4 nm. If it is a 3-nm thick single layer film made of a high-dielectric-constant film (HfSiON, HfO₂, or the like) with a dielectric constant k₁=20, its electrical film thickness is 0.99 nm. If it is a film stack of a 3-nm thick high-dielectric-constant film with k₁=20 and a 0.5 nm thick SiO₂ film, its electrical film thickness is 1.5 nm.

On the other hand, the electrical film thickness of the BOX layer is influenced by the thickness of a depletion layer which has occurred in upper and lower Si. The thickness of the depletion layer largely depends on the operation state of the device or concentration of the substrate so that it is difficult to define the thickness of the BOX layer in a similar manner to that employed for defining the thickness of the gate insulating film. In the present embodiment, therefore, the electrical film thickness of the BOX layer itself is defined. The electrical film thickness of the BOX layer is defined as T₁×3.9/k₁+T₂×3.9/k₂+ . . . . In particular, when the BOX layer is SiO₂, the electrical film thickness coincides with the actual film thickness. The reason of it may be that the BOX layer is thicker than the gate insulating film by about one order of magnitude. This definition provides the lower limit of the electrical film thickness.

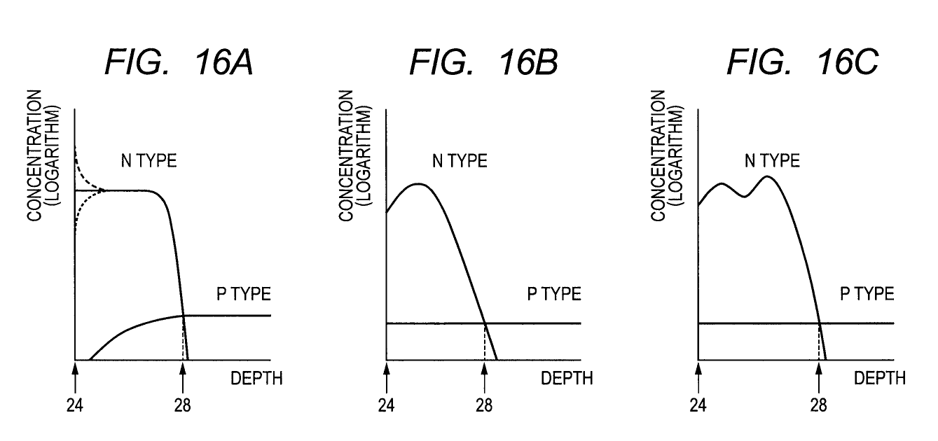

The N type semiconductor layer 104 (second conductivity type layer) has a concentration profile as shown in FIGS. 16(a), 16(b) and 16(c) depending on the formation method. FIGS. 16(a), 16(b), and 16(c) each show an impurity concentration below the BOX layer (insulating layer 106). FIG. 16(a) shows an impurity concentration profile when the N type semiconductor layer 104 is formed by epitaxial growth. FIG. 16(b) shows an impurity concentration profile when the N type semiconductor layer 104 is formed by single ion implantation. FIG. 16(c) shows an impurity concentration when the N type semiconductor layer 104 is formed by double ion implantation. A first plane 24 is the top surface of the N type semiconductor layer 104 to be brought into contact with the insulating layer 106. A PN junction plane 28 is a portion in which the N type impurity concentration of the N type semiconductor layer 104 and the P type impurity concentration of the P type semiconductor layer 102 coincide with each other. In other words, such an N type semiconductor layer 104 has, in a layer thickness direction thereof, a region having a uniform concentration. As shown FIG. 16(a), when epitaxial growth is employed, the concentration profile has a uniform distribution from the first plane 24 to the PN junction plane 28. On the other hand, as shown in FIGS. 16(b) and 16(c), single ion implantation provides a bell-shape distribution having a peak and double ion implantation provides a distribution with two peaks. Here, the depth (film thickness) of the N type semiconductor layer 104 is designated as a distance from the surface (first plane 24) to the PN junction (PN junction plane 28). The impurity concentration of the N type semiconductor layer 104 is designated, for example, as an average of the concentration within a depth range. Based on these definitions, it is effective that in the above equation, the N type semiconductor layer 104 satisfies the depth >W.

The N type semiconductor layer 104 is formed, as described above, so as to have a high impurity concentration without giving an influence on the transistor. The N type semiconductor layer 104 therefore has low resistance and is prevented from depletion. In addition, the N type semiconductor layer 104 is formed so as to have an increased effective film thickness.

In the present embodiment, each configuration of the semiconductor device 100, that is, the P type semiconductor layer 102, the N type semiconductor layer 104, the insulating layer 106, and the SOI layer 108 can be obtained from each configuration of the semiconductor wafer 10. A protecting film such as SiO₂ may be provided on the SOI layer. The N type and the P type are exchangeable.

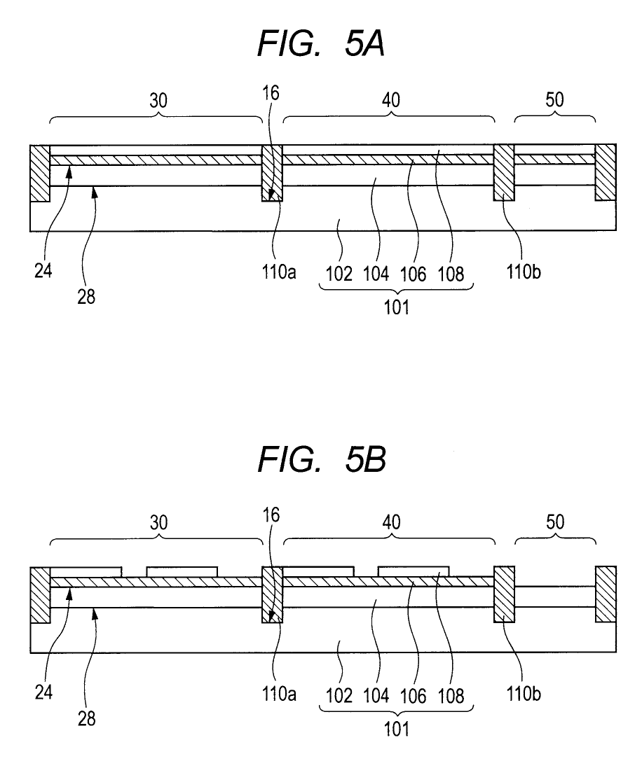

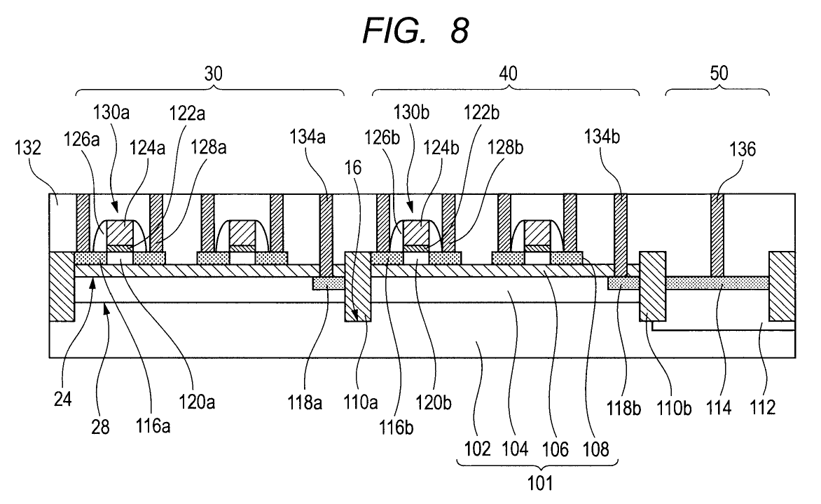

Then, a description will next be made on the manufacturing method of the semiconductor device according to the present embodiment. FIGS. 5(a) and (b) to FIG. 8 are cross-sectional views of steps showing the manufacturing procedures of the semiconductor device. The manufacturing method of the semiconductor device of the present embodiment has the following steps. First, a SOI substrate 101 having a semiconductor substrate 12 having, on a first conductivity type layer (P type semiconductor layer 102), a second conductivity type layer (N type semiconductor layer 104), an insulating layer (insulating layer 106) formed on the semiconductor substrate 12, and a semiconductor layer (SOI layer 108) formed on the insulating layer (insulating layer 106) is prepared. Then, a first element isolation insulating layer which is buried in the SOI substrate 101, has a lower end 16 reaching the first conductivity type layer (P type semiconductor layer 102), and isolates a first element region (PFET region 40) from a second element region (NFET region 30) is formed. Then, a first conductivity type first transistor (P type transistor 130b) located in the first element region (PFET region 40) and having a channel region 120b formed in the semiconductor layer (SOI layer 108) is formed. Then, a second conductivity type first transistor (N type transistor 130a) located in the second element region (NFET region 30) and having a channel region 120a formed in the semiconductor layer (SOI layer 108) is formed. Then, a first back gate contact (back gate contact 134b) is coupled to the second conductivity type layer (N type semiconductor layer 104) located in the first element region (PFET region 40). A second back gate contact (back gate contact 134a) is then coupled to the second conductivity type layer (N type semiconductor layer 104) located in the second element region (NFET region 30).

The manufacturing method of the semiconductor device 100 of the present embodiment may have the following steps further. Described specifically, the insulating layer (insulating layer 106) and the second semiconductor layer (N type semiconductor layer 104) are removed selectively to form a substrate contact region 50. Then, with an element isolation film (element isolation layer 110b), the SOI region (the NFET region 30 and the PFET region 40) is isolated from the substrate contact region 50. Then, a third well (P well 112) having a first conductivity type is formed in the semiconductor substrate 12 of the substrate contact region 50. Then, a substrate contact (contact 136) is formed over the third well (P well 112). These steps will next be described more specifically.

First, the above-described semiconductor wafer 10 is prepared. Then, as shown in FIG. 5(a), element isolation layers 110a and 110b (STI (Shallow Trench Isolation)) are formed in the semiconductor substrate 12. For example, lithography and etching are employed to form trenches. These trenches each have a depth deeper than the N type semiconductor layer 104. With them, the N type semiconductor layer 104 is isolated into a plurality of regions (having usually a rectangular or polygonal shape viewed from above). These regions each function as a back gate (BG). Then, the trench is filled with an insulator (such as SiO₂). Then, planarization is performed by CMP to leave the insulator only in the trench. As a result, the structure shown in FIG. 5(a) is formed. Incidentally, it is preferred to cover the whole surface with a protecting film such as a film stack of SiN/SiO₂ prior to the formation of trenches in order to protect the SOI layer 108 from damage by CMP. In this case, the protecting film is removed after CMP and the structure shown in FIG. 5(a) can be obtained. Thus, BG can be formed without carrying out ion implantation penetrating through the SOI layer.

Then, as shown in FIG. 5(b), the SOI layer 108 is patterned into a shape of a transistor as needed. The SOT layer 108 may be separated spatially by a recess portion (trench portion). Alternatively, it may be separated physically by element isolation. This means that in this step, a typical mesa isolation technology or STI technology can be employed. In the present embodiment, an example using a mesa isolation technology is shown.

Then, the N type semiconductor layer 104 and the insulating layer 106 located in the substrate contact region 50 are selectively removed, by which the top surface of the N type semiconductor layer 104 is exposed. Incidentally, in the present step, the whole or a portion of the insulating layer 106 may be remained. Alternatively, the N type semiconductor layer 104 may be removed selectively only from the substrate contact region 50 and then, selective Si growth may be conducted to obtain a uniform substrate height.

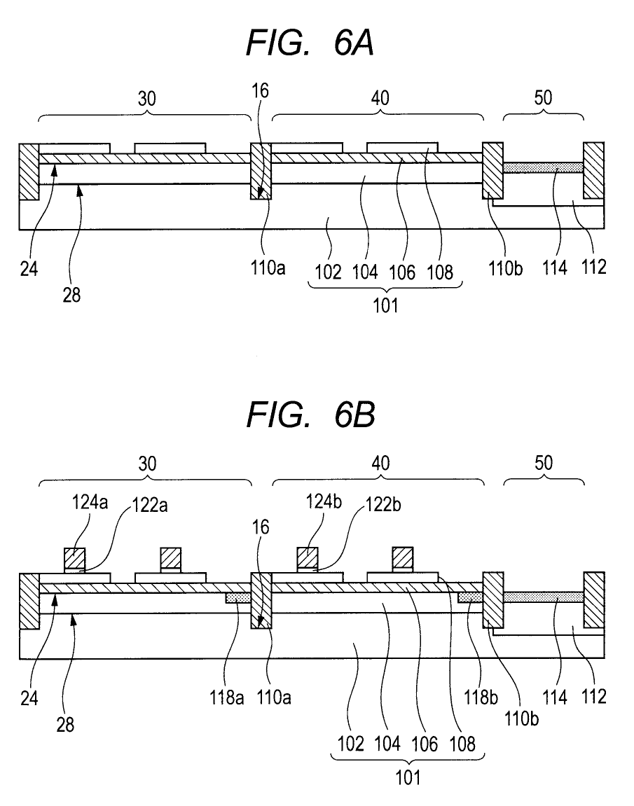

Then, as shown in FIG. 6(a), the P type diffusion layer 114 and the P well 112 are selectively formed in the semiconductor substrate 12 of the substrate contact region 50. For example, ion implantation or epitaxial growth is performed to form the P type diffusion layer 114 and the P well 112.

Then, as shown in FIG. 6(b), a gate insulating layer 122a and a gate electrode 124a are formed on the SOI layer 108 in the NFET region 30. In addition, a gate insulating layer 122b and a gate electrode 124b are formed on the SOI layer 108 in the PFET region 40. For example, a silicon oxynitride film and a polycrystalline silicon film are formed successively on the SOI layer 108. Lithography and dry etching are then used to process them into a gate electrode.

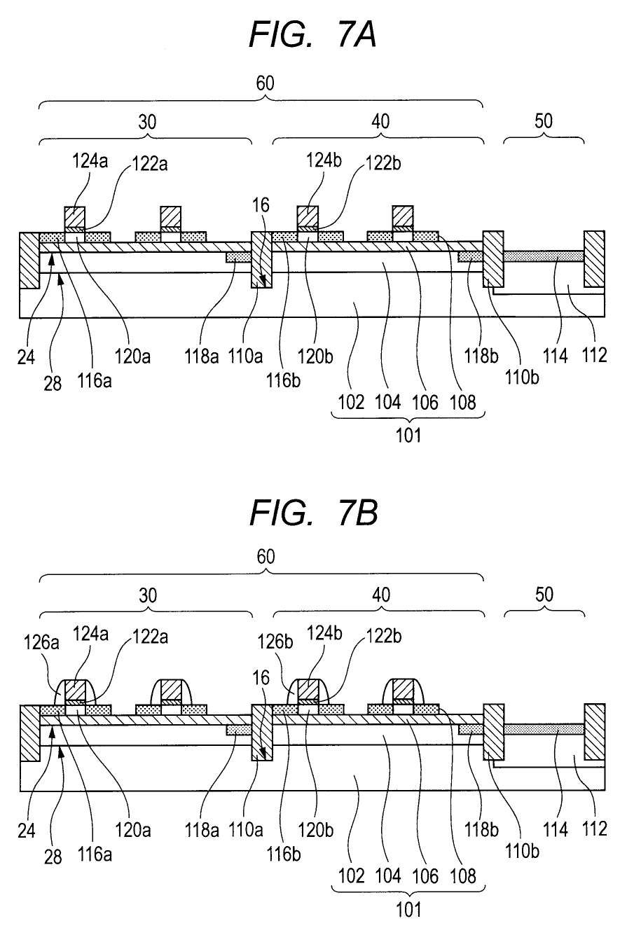

Then, as shown in FIG. 7(a), source drain diffusion layers (N type diffusion region 116a and P type diffusion region 116b) are formed in the SOI layers 108 on both sides of the gate electrodes 124a and 124b, respectively. For example, methods such as ion implantation and gas phase doping are employed. Simultaneously with this step, heavily doped N type diffusion layers (N type diffusion layers 118a and 118b) may be formed in a region of the N type semiconductor layer 104 in which a contact with BG is to be formed. The N type diffusion layers 118a and 118b may be omitted if the impurity concentration of the surface of the N type semiconductor layer 104 is sufficiently high. Simultaneously with this step, the above-described P type diffusion layer 114 may be formed in the semiconductor substrate 12 of the substrate contact region 50. In addition, after formation of the source drain diffusion layers, silicide is formed on the top surface of the source drain diffusion layers to make them low-resistant.

Then, as shown in FIG. 7(b), spacers 126a and 126b are formed on both walls of the gate electrodes 124a and 124b, respectively.

As shown in FIG. 8 and FIG. 4, an interlayer insulating layer 132 is formed on the semiconductor substrate 12. Contacts (contacts 128a and 128b, back gate contacts 134a and 134b, contacts 138a and 138b, and a contact 136) coupled to the source drain diffusion layers, back gates (end plates 118a and 118b), gate electrodes (gate electrodes 124a and 124b), and the semiconductor substrate 12 of the substrate contact region 50, penetrating through the interlayer insulating layer 132 are formed. The semiconductor device 100 can be obtained by the above-described steps.

The advantage and effect of the present embodiment will next be described. As described in Patent Documents 1 to 3, it is difficult to decrease the distance between BGs by using a method of isolating PN regions only by a PN junction. In other words, the configurations of Patent Documents 1 and 2 cannot decrease the isolation distance between wells, which leads to deterioration in the degree of integration (because no STI is present between wells in Document 1, while wells of NFET and PFET have respectively different polarities in Document 2). In addition, when as Patent Documents 1 and 2 and Non-patent Document 1, wells are formed by ion implantation penetrating through a SOI layer, impurities remain in the SOI layer and deteriorate the transistor characteristics (cause a variation in the characteristics).

In the present embodiment, on the other hand, the distance between different BGs is determined by the minimum processable width of STI so that a high degree of integration can be achieved. In addition, since the BGs are buried in the substrate in advance so that it is not necessary to form BGs by ion implantation. There is therefore no possibility of implanted impurities being mixed in the SOI layer of a FET and the resulting FET can have a high performance. The present embodiment therefore makes it possible to form LSIs having BG below a BOX layer easily and at the same time, with a high degree of integration.

In a semiconductor device equipped with a SOI substrate having a thin-film SOI layer, it is necessary to reduce a variation by not introducing impurities into the thin-layer SOI layer. It may become difficult to control the Vth of such a semiconductor device by impurities.

In the present embodiment, on the other hand, as shown in FIG. 1, independent potentials can be applied to the BG of NFET and the BG of PFET, by which the threshold values Vth of the NFET and PFET can be controlled independently and their threshold values Vth can be set at the optimum values, respectively. The BGs isolated from each other are electrically isolated by a PN junction. In order to achieve isolation more definitely, it is desired to make the STI depth sufficiently deeper than the bottom surface of the N type layer. Although the BGs are shared by all the NFETs or shared by all the PFETs, it is possible to isolate BGs from each other in the NFETs or in PFETs and thereby differentiate the potential of the BGs in the NFETs or in the PFETs. Such a configuration enables realization of multi Vth. Furthermore, the potential of the BG is not required to be fixed and can be changed as needed depending on the operation state of a circuit. This enables realization of variable Vth.

### Second Embodiment

A semiconductor device 100 of a second embodiment is similar to that of the first embodiment except that it has a bulk PFET region 70 and a bulk NFET region 80. A difference from the first embodiment will next be described.

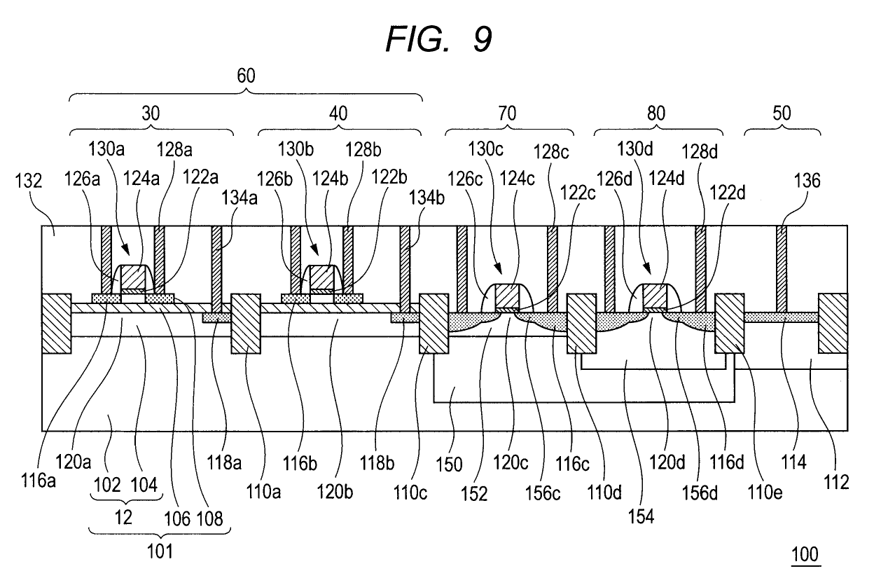

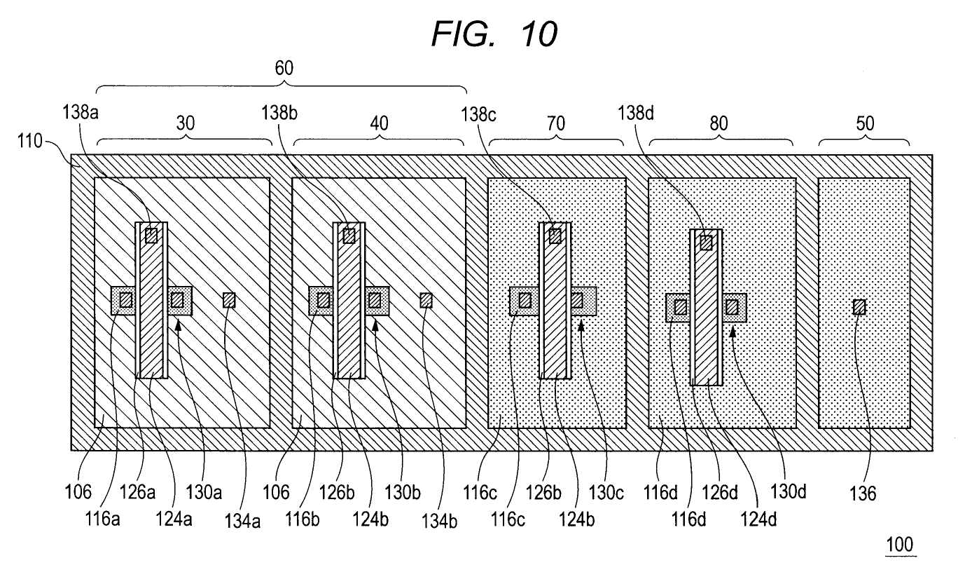

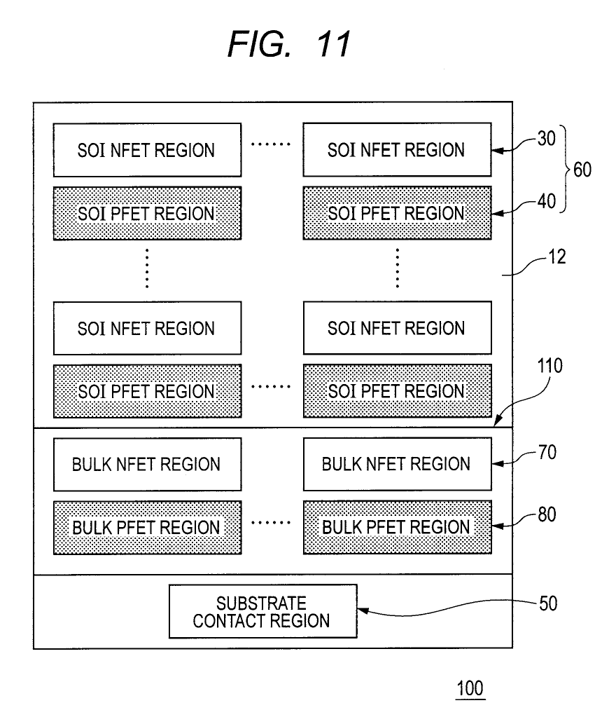

FIG. 9 is a cross-sectional view showing the configuration of the semiconductor device according to the second embodiment. FIG. 10 is a plan view showing the configuration of the semiconductor device according to the second embodiment. FIG. 11 shows an example of the layout of the semiconductor device according to the second embodiment. The semiconductor device 100 of the second embodiment is equipped with a semiconductor substrate, a first element isolation insulating layer, a second element isolation insulating layer, a first conductivity type first transistor, a second conductivity type first transistor, a second conductivity type second transistor, a first back gate contact, and a second back gate contact.

A semiconductor substrate 12 has a first conductivity type layer (P type semiconductor layer 102) and a second conductivity type layer (N type semiconductor layer 104) formed thereon. A second element isolation layer (element isolation layer 110c) is buried in the semiconductor substrate 12, has a lower end reaching the P type semiconductor layer 102, and isolates a SOI region 60 and a bulk region (bulk PFET region 70) from each other. The SOI region 60 further has an insulating layer (insulating layer 106) formed on the semiconductor substrate 12 and a semiconductor layer (SOI layer 108) formed on the insulating layer 106. A first element isolation insulating layer (element isolation layer 110a) is buried in the semiconductor substrate 12 located in the SOI region 60, has a lower end reaching the P type semiconductor layer 102, and isolates a first element region (PFET region 40) and a second element region (NFET region 30) from each other.

A first conductivity type first transistor (P type transistor 130b) is located in the PFET region 40 and is equipped with a channel region 120b formed in the SOI layer 108. A second conductivity type first transistor (N type transistor 130a) is located in the NFET region 30 and is equipped with a channel region 120a formed in the SOI layer 108. A first back gate contact (back gate contact 134b) is coupled to the second conductivity type layer (SOI layer 108) located in the first element region (PFET region 40). A second back gate contact is coupled to the second conductivity type layer (SOI layer 108) located in the second element region (NFET region 30).

A first conductivity type second transistor (P type transistor 130c) is located in the bulk PFET region 70 and formed on the second conductivity type layer (N well 152). The semiconductor device 100 having such a configuration is specified by that the second conductivity type impurity concentration of the second conductivity type layer (N type semiconductor layer 104) is 10¹⁸ atoms/cm³ or greater and the second conductivity type impurity concentration in the semiconductor layer (SOI layer 108) on which the first conductivity type transistor (P type transistor 130b) has been formed is 1/10 or less of the second conductivity type impurity concentration of the second conductivity type layer (N type semiconductor layer 104) located in the PFET region 40.

The semiconductor device 100 of the second embodiment may further have the following configuration shown in FIG. 9. Described specifically, the semiconductor device 100 of the present embodiment is equipped further with a bulk region comprised of a bulk PFET region 70 and a bulk NFET region 80 and a substrate contact region 50. In the bulk region, a third element isolation insulating layer (element isolation layer 110d) is buried in the semiconductor substrate 12 and isolates the third element region (bulk PFET region 70) from the fourth element region (bulk NFET region 80).

In the bulk PFET region 70, a P type transistor 130c is formed. The P type transistor 130c is equipped with a gate insulating layer 122c and a gate electrode 124c, each formed over the N well 152, and P type diffusion regions 116c and P type extension regions 156c formed on both sides of the gate electrode 124c and in the vicinity of the surface of the N well 152. The gate electrode 124 has, on both walls thereof, a spacer 126c. A contact 128c is coupled to each of the P type extension regions 156c. An N well 150 (second conductivity type well) is formed between the N well 152 and the P type semiconductor layer 102. In the present embodiment, the second conductivity type layer located in the bulk PFET region 70 (bulk region) may be the N well 152, but may be the same as the N type semiconductor layer 104 located in the SOI region 60. In the present embodiment, the term “may be the same as” means “may have an impurity of the same conductivity type and have a concentration profile with the same tendency”.

An N type transistor 130d (second conductivity type second transistor) is formed in the bulk NFET region 80. A P well 154 (first conductivity type first well) is formed in the upper layer of the semiconductor substrate 12 located in the bulk NFET region 80 and the N type transistor 130d is formed on this P well 154. The N type transistor 130d is equipped with a gate insulating layer 122d and a gate electrode 124d, each formed on the P well 154, and N type diffusion region 116d and N type extension region 156d formed on both sides of a gate electrode 124d and in the vicinity of the surface of the P well 154. The gate electrode 124d has, on both sides thereof, a spacer 126d. A contact 128d is coupled to each of the N type extension regions 156d.

For example, when the N well 150 is formed by ion implantation and the P well 154 is formed by epitaxial growth, the N type impurity shows a bell-shaped concentration profile, while the P type impurity shows a uniform profile. This means that in a region having the P well 154 formed therein, there exists an overlapping region of a bell-shaped profile and a uniform profile of an impurity having an opposite conductivity type.

As shown in FIG. 10, in a planar view, neither the SOI layer 108 nor the insulating layer 106 is formed on the surface of each of the P type diffusion region 116c and the N type diffusion region 116d. Depending on a variation in removal in the removing step, however, they may remain on the surface insofar as they do not impair the operation of a transistor.

The bulk region and the substrate contact region 50 are isolated from each other with the element isolation layer 110e. The substrate contact region 50 has therein a contact 136. The contact 136 is coupled to the P well 112 of the substrate contact region 50 via the P type diffusion layer 114.

Next, an advantage and effect of the second embodiment will be described. The SOI device of the second embodiment may be embedded together with a bulk device. If the SOI layer and the BOX layer are thin, a typical bulk MOSFET can be formed in a substrate below the BOX layer by removing only a portion of these layers without causing a large step difference. In addition, the semiconductor device of the second embodiment can produce an effect similar to that of the semiconductor device of the first embodiment.

In the present embodiment, as shown in FIG. 11, a plurality of SOI NFET regions (NFET regions 30) and SOI PFET regions (PFET regions 40) are placed on the chip. The SOI NFETs and SOI PFETs are combined to configure a CMOS circuit. Below the BOX layers in these regions, BGs are placed, respectively, so that potentials thereof can be set independently. In addition, a bulk CMOS formation region is provided. The bulk CMOS formation region has a plurality of bulk PFET regions 70 (P well regions) and bulk NFET regions 80 (N well regions). The bulk NFETs and the bulk PFETs are combined to configure a bulk CMOS circuit. The bulk FET is suited for use in an I/O circuit and an analogue circuit.

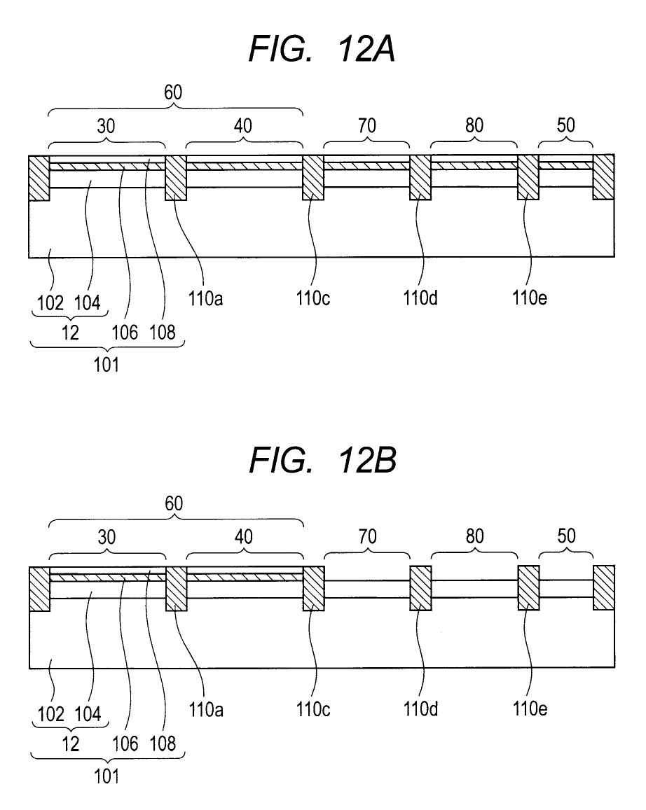

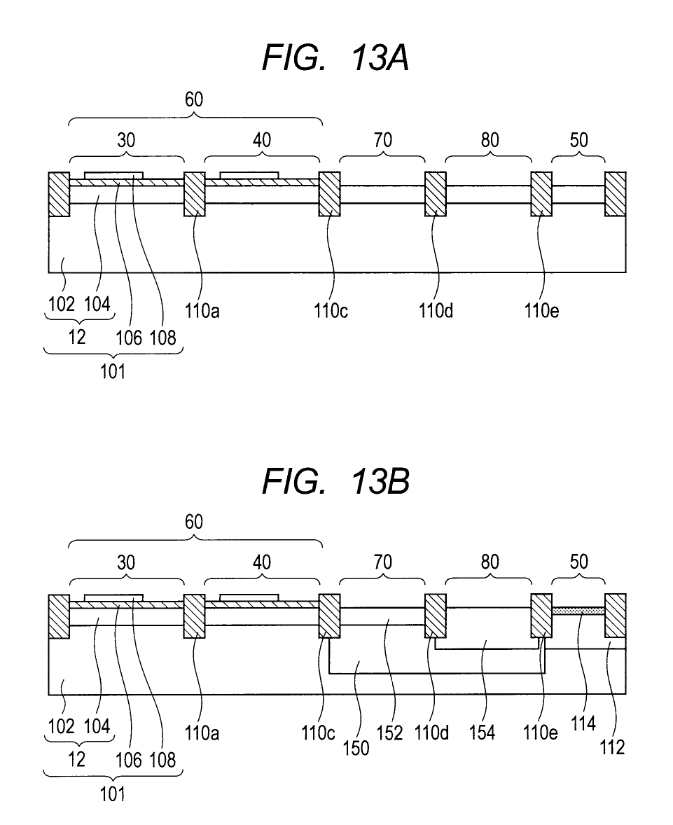

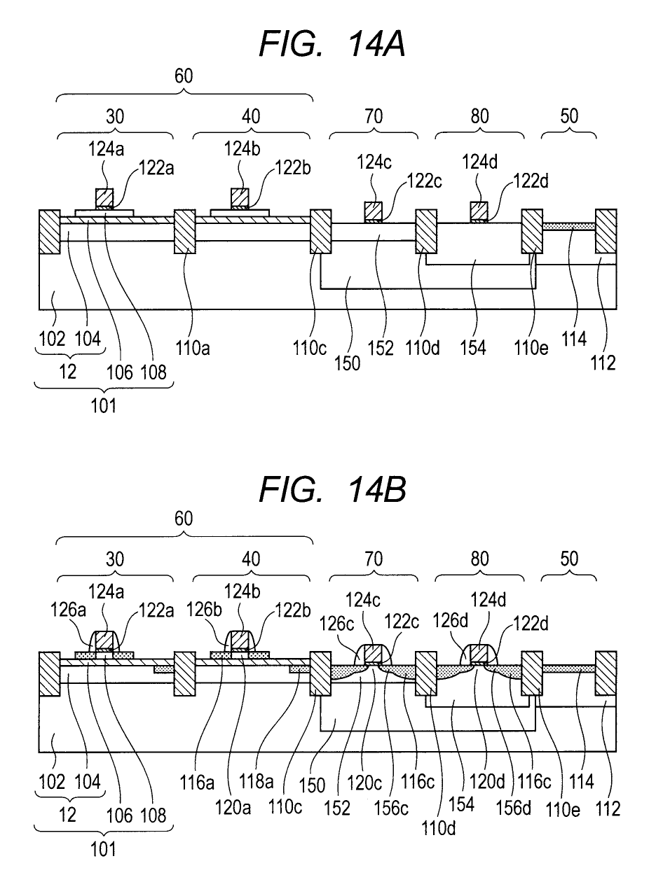

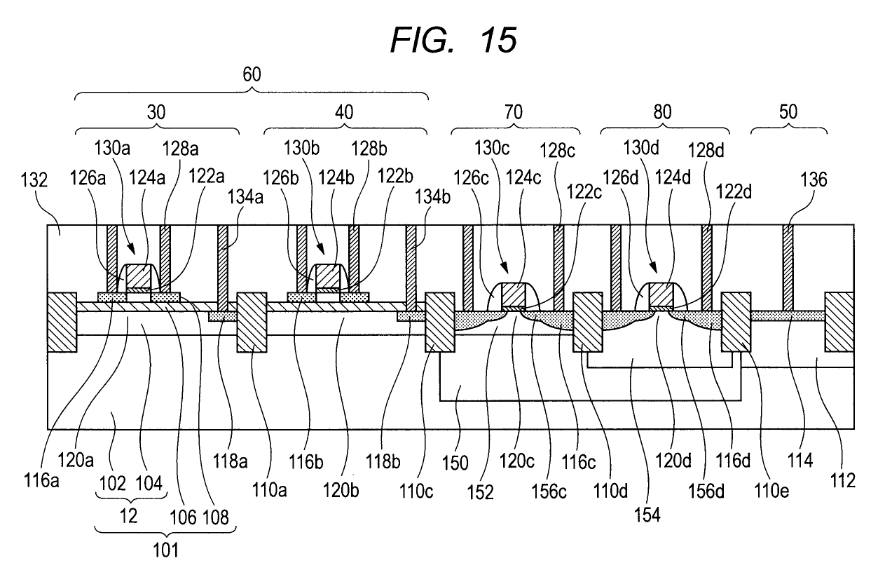

Then, a manufacturing method of the semiconductor device according to the second embodiment will be described. FIGS. 12(a) and (b), FIGS. 13(a) and (b), FIGS. 14(a) and (b), and FIGS. 15(a) and (b) are cross-sectional views of steps showing the procedures of the manufacturing method of the present embodiment. The manufacturing method of the semiconductor device of the present embodiment includes the following steps. Similar to the first embodiment, a step of forming a first conductivity type first transistor (P type transistor 130b), a step of forming a second conductivity type first transistor (N type transistor 130a), a step of coupling a first back gate contact (back gate contact 134b), and a step of coupling a second back gate contact (back gate contact 134a) are conducted over a semiconductor substrate 12 located in a SOI region 60. An insulating layer 106 and a semiconductor layer (SOI layer 108) are removed selectively to form a bulk region over the semiconductor substrate 12. Then, a second element isolation layer (element isolation layer 110c) buried in the semiconductor substrate 12, having a lower end reaching the first conductivity type layer (P type semiconductor layer 102), and isolating the bulk region and the SOI region from each other is formed. A first conductivity type second transistor (P type transistor 130c) is formed on a second conductivity type layer (N well 152) located in the bulk region. Furthermore, the manufacturing method of the semiconductor device of the present embodiment may have the following steps. In the bulk region, a third element isolation insulating layer (element isolation layer 110d) buried in the semiconductor substrate 12 and isolating a third element region (bulk PFET region 70) and a fourth element region (bulk NFET region 80) from each other is formed. Then, a first conductivity type first well (P well 154) is formed in the upper layer of the semiconductor substrate 12 located in the bulk NFET region 80. Then, a second conductivity type second transistor (N type transistor 130d) is formed on the P well 154 in the bulk NFET region 80. A second conductivity type well (N well 150) may be formed in the semiconductor substrate 12 located in the bulk PFET region 70 and between the second conductivity type layer (N well 152) and the first conductivity type layer (P type semiconductor layer 102). These steps will next be described in detail.

First, as shown in FIG. 12(a), element isolation layers 110a, 110c to 110e which isolate regions from each other are formed in the SOI substrate 101. With these layers, the SOI substrate 101 is divided into an NFET region 30, a PFET region 40, a bulk PFET region 70, a bulk NFET region 80, and a substrate contact region 50.

Next, as shown in FIG. 12(b), both in the bulk region and the substrate contact region 50, the insulating layer 106 and the SOI layer 108 are removed selectively. On the other hand, in the SOI region 60, as shown in FIG. 13(a), the SOI layer 108 is patterned into a predetermined shape.

Next, as shown in FIG. 13(b), a well is formed in the semiconductor substrate 12 in the bulk region. For example, an N well 150 covering therewith the bulk PFET region 70 and the bulk NFET region 80 is formed. An N well 152 is formed on the N well 150 in the bulk PFET region 70. A P well 154 is formed on the N well 150 in the bulk NFET region 80. The impurity concentration of the N well 152 is preferably made greater than that of the N well 150, while the impurity concentration of the P well 154 is preferably made greater than that of the N well 150.

It is desired to selectively remove the N type Si layer only from the bulk FET region and then, carry out selective Si growth in order to make the height of the substrate equal. These N well and P well can be formed by ion implantation. It is also possible to use the originally present N type Si layer as the N well without removing the N type Si layer 104. At this time, the P well can be formed by introducing P type impurities by ion implantation. Incidentally, when the concentration of the N type Si layer (N type semiconductor layer 104) below the BOX layer is too high, the well may be formed after reducing the concentration by outward diffusion. In addition, it is also possible to form a deep N well (N well 150) shown in FIG. 13(b), electrically isolate the P well for bulk FET from the P type Si substrate to make their potentials different from each other.

In the present step, a P well 112 and a P type diffusion layer 114 are formed in the semiconductor substrate 12 of the substrate contact region 50. The P well 112 may be formed in a step similar to that of the P well 154 or it may be formed simultaneously with a step of forming a P type diffusion region 116c which will be described later. The P type diffusion layer 114 may be formed at arbitrary timing, which will be described later.

Next, as shown in FIG. 14(a), a gate insulating layer 122a and a gate electrode 124a are formed on the SOI layer 108 in the NFET region 30. In addition, a gate insulating layer 122b and a gate electrode 124b are formed on the SOI layer 108 in the PFET region 40. A gate insulating film and a gate electrode are formed in the bulk PFET region 70 and the bulk NFET region 80 as well as the SOI region 60. Described specifically, a gate insulating layer 122c and a gate electrode 124c are formed on the N well 152 in the bulk PEFET region 70. A gate insulating layer 122d and a gate electrode 124d are formed on the P well 154 in the bulk NFET region 80. For example, a silicon oxynitride film and a polycrystalline silicon film are formed successively on the SOI layer 108, the N well 152, and the P well 154, followed by lithography and dry etching to process them into these gate electrodes.

Then, as shown in FIG. 14(b), extension regions (P type extension region 156c and N type extension region 156d) are formed in the N well 152 and P well 154 on both sides of the gate electrodes 124c and 124d, respectively. At the same time with this step, source drain diffusion layers (N type diffusion region 116a and P type diffusion region 116b) can be formed in the SOI layer 108 on both sides of the gate electrodes 124a and 124b, respectively. For example, ion implantation or gas phase doping can be employed. At the same time with this step, a P type diffusion layer 114 of the substrate contact region 50 may be formed.

Next, a spacer 126d is formed on both walls of the gate electrode 124d. Then, source drain diffusion layers (P type diffusion regions 116c and N type diffusion regions 116d) are formed in the N well 152 and the P well 154 on both sides of the gate electrodes 124c and 124d, respectively. For example, ion implantation or gas phase doping is employed. The resistance may be decreased by forming silicide on the top surface of the source drain diffusion layer. Simultaneously with the formation step of the extension regions or source drain diffusion layers, heavily-doped N type diffusion layers (N type diffusion layers 118a and 118b) may be formed in a region of the N type semiconductor layer 104 in which a contact with BG is formed. The N type diffusion layers 118a and 118b may be omitted if the impurity concentration on the surface of the N type semiconductor layer 104 is sufficiently high.

Next, as shown in FIG. 15, an interlayer insulating layer 132 is formed over the semiconductor substrate 12, followed by the formation of contacts (contacts 128a and 128b, back gate contacts 134a and 134b, contacts 138a and 138b, contacts 128c and 128d, and a contact 136) penetrating through this interlayer insulating layer 132 and coupled to the source drain diffusion layers, back gates (end plates 118a and 118b), and gate electrodes (gate electrodes 124a and 124b), and the semiconductor substrate 12 in the bulk MOSFET regions (bulk PFET region 70 and bulk NFET region 80) and the substrate contact region 50. In such a manner, the semiconductor device 100 of the second embodiment can be obtained.

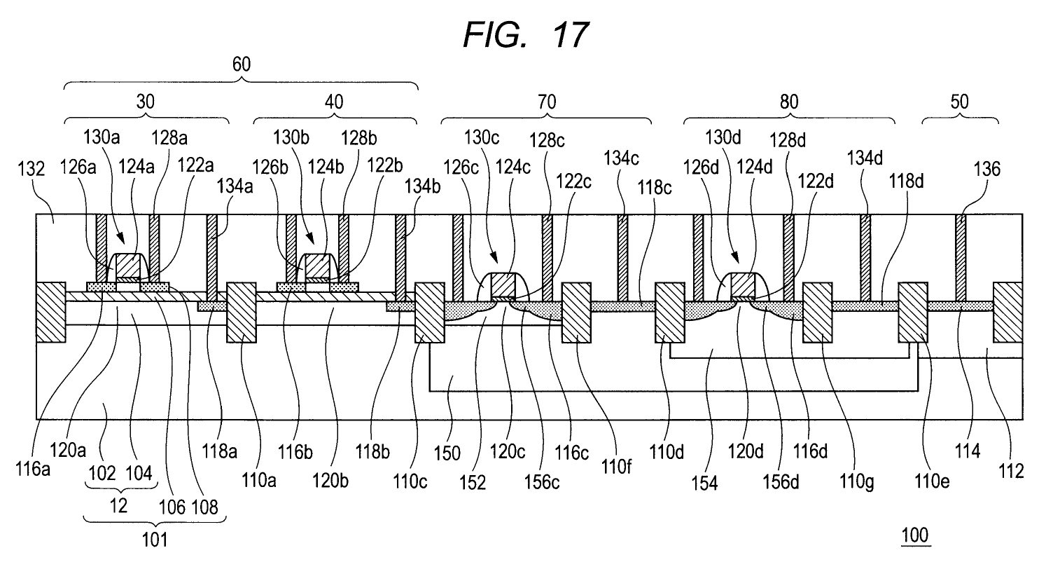

FIG. 17 is a plan view showing a modification example of the configuration of the semiconductor device of the second embodiment. As shown in FIG. 17, a well contact may be formed in order to adjust the potential of each of the N well 150 and the P well 154. A well contact 134c is isolated from the transistor 130c present in the bulk PFET region 70 by an element isolation layer 110f and is coupled to the N well 150 via the N type diffusion layer 118c. A well contact 134d is isolated from the transistor 130d present in the bulk NFET region 80 by an element isolation layer 110g and is coupled to the P well 154 via the P type diffusion layer 118d. The N type diffusion layer 118c may be omitted if the impurity concentration of the surface of the N well 150 is sufficiently high. The P type diffusion layer 118d may be omitted if the impurity concentration of the surface of the P well 154 is sufficiently high.

It is to be noted that in the above description, the N types and the P types may be completely interchanged with each other. In this case, with regard to the applied voltage, replacement for reversing the polarity is conducted.

It is needless to say that the above-described embodiments and a plurality of modification examples may be used in combination insofar as they are not contrary to each other. In the above embodiments and modification examples, the structure of each portion was described specifically, but the structure can be changed insofar as the changed structure can satisfy the invention.

1. A semiconductor device comprising:
a SOI substrate having a semiconductor substrate having a first conductivity type layer and a second conductivity type layer formed thereover, an insulating layer formed over the semiconductor substrate, and a semiconductor layer formed over the insulating layer;
a first element isolation insulating layer buried in the SOI substrate, having a lower end reaching the first conductivity type layer, and isolating a first element region from a second element region;
a first conductivity type transistor located in the first element region and having a channel region formed in the semiconductor layer;
a second conductivity type transistor located in the second element region and having a channel region formed in the semiconductor layer;
a first back gate contact coupled to the second conductivity type layer located in the first element region; and
a second back gate contact coupled to the second conductivity type layer located in the second element region,
wherein the second conductivity type impurity concentration of the second conductivity type layer is 10¹⁸ atoms/cm³ or greater, and
wherein the second conductivity type impurity concentration of the semiconductor layer over which the first conductivity type transistor is formed is not greater than 1/10 of the second conductivity type impurity concentration the second conductivity type layer.

2. A semiconductor device comprising:
a semiconductor substrate having a first conductivity type layer and a second conductivity type layer formed thereover;
a second element isolation layer buried in the semiconductor substrate, having a lower end reaching the first conductivity type layer, and isolating, from a bulk region, a SOI region further having both an insulating layer formed over the semiconductor substrate and a semiconductor layer formed over the insulating layer;
a first element isolation insulating layer buried in the semiconductor substrate located in the SOI region, having a lower end reaching the first conductivity type layer, and isolating a first element region from a second element region;
a first conductivity type first transistor located in the first element region and having a channel region formed in the semiconductor layer;
a second conductivity type first transistor located in the second element region and having a channel region formed in the semiconductor layer;
a first conductivity type second transistor located in the bulk region and formed over the second conductivity type layer;
a first back gate contact coupled to the second conductivity type layer located in the first element region; and
a second back gate contact coupled to the second conductivity type layer located in the second element region,
wherein the second conductivity type impurity concentration of the second conductivity type layer is 10¹⁸ atoms/cm³ or greater, and
wherein the second conductivity type impurity concentration of the semiconductor layer over which the first conductivity type transistor is formed is not greater than 1/10 of the second conductivity type impurity concentration of the second conductivity type layer.

3. The semiconductor device according to claim 2, wherein the second conductivity type layer located in the SOI region and the second conductivity type layer located in the bulk region are the same.

4. The semiconductor device according to claim 2, further comprising in the bulk region:
a third element isolation insulating layer buried in the semiconductor substrate and isolating a third element region from a fourth element region;
a second conductivity type first well formed in the upper layer of the semiconductor substrate located in the fourth element region;
the first conductivity type second transistor located in the third element region and formed over the second conductivity type layer; and
a second conductivity type second transistor located in the fourth element region and formed over the first conductivity type well.

5. The semiconductor device according to claim 2, further comprising:
a second conductivity type well formed in the semiconductor substrate located in the bulk region and formed between the second conductivity type layer and the first conductivity type layer.

6. The semiconductor device according to claim 1, wherein the insulating layer has a thickness of 20 nm or less.

7. The semiconductor device according to claim 1, wherein the thickness of the insulating layer is not greater than 10 times the minimum line width of a gate electrode of the first conductivity type transistor located in the first element region.

8. The semiconductor device according to claim 1, further comprising:
a third element isolation insulating layer buried in the SOI substrate or the semiconductor substrate located in the SOI region, having a lower end reaching the first conductivity type layer, and isolating an element region including the first element region and the second element region from a substrate contact region;
a first conductivity type second well located in the substrate contact region and formed in the upper layer of the semiconductor substrate; and
a substrate contact located in the substrate contact region and coupled to the first conductivity type second well.

9. The semiconductor device according to claim 8,
wherein the semiconductor substrate located in the substrate contact region does not have the insulating layer thereover.

10. The semiconductor device according to claim 8,
wherein the semiconductor substrate located in the substrate contact region has thereover the insulating layer, and
wherein the substrate contact penetrates through the insulating layer and is coupled to the first conductivity type well.

11. The semiconductor device according to claim 1, wherein the first element isolation insulating layer has a lower end thereof in the first conductivity type layer.

12. The semiconductor device according to claim 1, wherein the element isolation insulating layer has an aspect ratio not greater than 10.

13. The semiconductor device according to claim 1, wherein the second conductivity type layer has a region having a uniform concentration in the layer thickness direction.

14. A semiconductor wafer comprising:
a SOI substrate having a semiconductor substrate having a first conductivity type layer and a second conductivity type layer formed thereover, an insulating layer formed over the semiconductor substrate, and a semiconductor layer formed over the insulating layer,
wherein in a planar view, supposing that the area of the first conductivity type layer is S1 and the area of the second conductivity type layer is S2, a proportion of S2/S1 is 80% or greater.

15. The semiconductor wafer according to claim 14, wherein the second conductivity type layer is, in a planar view, formed continuously and the proportion of S2/S1 is 95% or greater.

16. The semiconductor wafer according to claim 14, wherein the insulating layer has a thickness of 20 nm or less.

17. The semiconductor wafer according to claim 14, wherein the second conductivity type layer has a thickness of 500 nm or less.

18. The semiconductor wafer according to claim 14, wherein the second conductivity type layer has an impurity concentration of 10¹⁸ atoms/cm³ or greater.

19. The semiconductor wafer according to claim 14, wherein the impurity concentration of the semiconductor layer is not greater than 1/10 of the second conductivity type impurity concentration of the second conductivity type layer.

20. A method of manufacturing a semiconductor device, comprising the steps of:
preparing a SOI substrate having a semiconductor substrate having a first conductivity type layer and a second conductivity type layer formed thereover, an insulating layer formed over the semiconductor substrate, and a semiconductor layer formed over the insulating layer;
forming a first element isolation insulating layer buried in the SOI substrate, having a lower end reaching the first conductivity type layer, and isolating a first element region from a second element region;
forming a first conductivity type first transistor located in the first element region and having a channel region formed in the semiconductor layer;
forming a second conductivity type first transistor located in the second element region and having a channel region formed in the semiconductor layer,
coupling a first back gate contact to the second conductive type layer located in the first element region; and
coupling a second back gate contact to the second conductivity type layer located in the second element region.

21. The method of manufacturing a semiconductor device according to claim 20, further comprising the steps of:
removing the insulating layer and the semiconductor layer selectively to form a bulk region over the semiconductor substrate;
forming a second element isolation layer buried in the semiconductor substrate, having a lower end reaching the first conductivity type layer, and isolating the bulk region from the SOI region; and
forming a first conductivity type second transistor over the second conductivity type layer in the bulk region,
wherein over the semiconductor substrate located in the SOI region, the step of forming the first conductivity type first transistor, the step of forming the second conductivity type first transistor, the step of coupling the first back gate contact, and the step of coupling the second back gate contact are conducted.

22. The method of manufacturing a semiconductor device according to claim 21, further comprising the steps of:
in the bulk region, forming a third element isolation insulating layer buried in the semiconductor substrate and isolating a third element region from a fourth element region;
forming a first conductivity type first well in the upper layer of the semiconductor substrate located in the fourth element region;
forming the first conductivity type second transistor located in the third element region over the second conductivity type layer; and
forming a second conductivity type second transistor located in the fourth element region over the first conductivity type well.

23. The method of manufacturing a semiconductor device according to claim 22, further comprising the step of:
forming a second conductivity type well in the semiconductor substrate located in the bulk region and between the second conductivity type layer and the first conductivity type layer.

24. The method of manufacturing a semiconductor device according to claim 20, further comprising the steps of:
selectively removing the insulating layer and the second semiconductor layer to form a substrate contact region;
isolating the SOI region from the substrate contact region with the element isolation film;
forming a first conductivity type third well over the semiconductor substrate in the substrate contact region; and
forming a substrate contact over the third well.

25. A method of manufacturing a semiconductor wafer, comprising the steps of:
forming a second conductivity type layer over a first conductivity type layer to obtain a first semiconductor substrate;
forming an insulating layer over a semiconductor layer to obtain a second semiconductor substrate; and
facing the second conductivity type layer and the insulating layer to bond the first semiconductor layer and the second semiconductor layer to each other.

26. The method of manufacturing a semiconductor wafer according to claim 25, wherein the second conductivity layer is formed by either epitaxial growth or ion implantation.
